(19) United States
(12) Patent Application Publication
(10) Pub. No.: US 2019/0128938 A1
(43) Pub. Date: May 2, 2019

(54) WIRELESS SCANNER

(71) Applicant: Ether Capital Corporation, Wilimington, DE (US)

(72) Inventors: Ruska Patton, Calgary (CA); Sammer Al-Robaee, Calgary (CA); Gil Montag, Calgary (CA)

(21) Appl. No.: 16/093,102

(22) PCT Filed: Apr. 13, 2017
(86) PCT No.: PCT/CA2017/050466

§ 371 Date: Oct. 11, 2018

Related U.S. Application Data
(60) Provisional application No. 62/323,208, filed on Apr. 15, 2016.

(51) Int. Cl. G01R 29/08

(52) U.S. Cl. CPC G01R 29/0871

(57) ABSTRACT

An RF scanning system and method includes a plurality of antenna probes and a plurality of RF receivers, wherein each probe is associated with a unique RF receiver, which outputs data to a digital signal processor.

### FIELD OF THE INVENTION

The present invention relates to systems and methods of measurement for characterizing antenna performance.

### BACKGROUND

Near-field measurement systems are widely used for the characterization of large and/or low frequency antennas for which far-field or compact range measurement systems become too costly and in some cases impractical to use. Near-field measurement systems are also used to investigate the near-field emissions from electrical devices to identify problems related to unintentional radiated emissions. In both applications, the compact size of these near-field measurement systems allows for integration of measurement probes in planar, circular, and other array configurations. If the measurements are done by an array of sensors, the mechanical movements of the probes, the antenna-under-test (AUT) or device-under-test (DUT) are reduced or eliminated, and hence the measurement time is reduced. In the case of planar near-field antenna measurements, the simplicity of the near-field to far-field transformation algorithms along with the array based approach results in almost real-time far-field characterization of the AUT or DUT in a hemisphere. A further reduction in measurement system size can be achieved if measurements can be done in the reactive region of the near-field, which is traditionally avoided because of the potential for reflection and coupling with the antenna.

Measurement in this reactive region is sometimes called very near-field measurement. An example of such a planar reactive near-field antenna measurement system is the RFxpert® product (EMSCAN Corp., Canada), which uses an array of rapidly switchable probes printed on a printed circuit board (PCB). The orthogonal magnetic field components (magnitude and phase) measured by the probes are transformed to a far-field pattern in a hemisphere using a plane-wave-spectrum (PWS) expansion.

Another example of a planar reactive near-field measurement system which provides information about unintentional emissions is the EMxpert® product (EMSCAN Corp., Canada). It uses the measured magnetic field components to predict currents on the DUT, which helps the user understand root causes of emissions problems that will hinder compliance testing.

These arrays rely on fast electronic switching between the probes rather than mechanical movements of the AUT in a chamber. The output from a specific probe is selected by means of layered radio frequency (RF) switches which can select the output from any one of the probes to direct to an RF receiver.

### SUMMARY OF THE INVENTION

The present invention relates to a scanner system of calibrating and/or correcting measurement made using a very near-field scanner of an antenna-under-test (AUT) or device-under-test (DUT). The scanner may comprise a device which uses an array of integrated probes that are each individually associated with a radio frequency (RF) receiver without intermediate switches or RF cables, to capture near-field data in proximity of an AUT or DUT. The scanner may transform the near field data into far-field data or represent currents on the DUT related to the measurements. Such measurement devices may measure the amplitude or phase and amplitude of the magnetic field (H-Field) or electric field (E-Field) in one, two or three orthogonal directions, in the reactive near-field, and use the H-field or E-field to project this data to the far-field, using a far field transformation method such as a planar aperture distribution to angular spectrum transformation or a plane wave spectrum (PWS) transformation.

Thus, in one aspect, the invention may comprise an RF scanning system comprising a plurality of antenna probes and a plurality of RF receivers, wherein each probe is associated with a unique RF receiver which outputs data to a digital signal processor.

In another aspect, the invention may comprise an RF scanning system comprising a plurality of antenna probes each connected to an RF receiver, wherein each antenna probe is separated from an RF receiver by an RF trace less than about 1 centimeter.

In another aspect, the invention may comprise a method of capturing data from an AUT or a DUT using a scanning system comprising a probe array comprising a plurality of probes and a plurality of RF receivers, comprising the steps of:
(a) sampling each probe with a unique RF receiver and outputting RF data from each receiver, and
(b) processing the RF data to recover measurement data from each probe.

### BRIEF DESCRIPTION OF THE DRAWINGS

In the drawings, like elements are assigned like reference numerals. The drawings are not necessarily to scale, with the emphasis instead placed upon the principles of the present invention. Additionally, each of the embodiments depicted are but one of a number of possible arrangements utilizing the fundamental concepts of the present invention.

FIG. 1 (PRIOR ART) shows a probe array connected to a system of layered switches, converging on a single RF receiver comprising a downconverter and an ADC.

FIG. 2 is a schematic representation of one embodiment of the present invention, whereby each probe is associated with a unique RF receiver made up of a downconvertor ⊗ and a sampler (ADC).

FIG. 3 is a schematic representation of another embodiment, where two groups of probes and receivers, each having a separate local oscillator and a clock, share one probe to permit downstream data alignment.

FIG. 4 is a schematic representation of a four-channel integrated microchip associated with 4 probes.

FIG. 5 is a schematic representation of one example of a scanning system having 1600 probes and 1600 receivers implemented into 70 integrated microchips.

FIG. 6 is a schematic representation of an alternative embodiment using digital signal processors and not FPGAs.

### DETAILED DESCRIPTION OF PREFERRED EMBODIMENTS

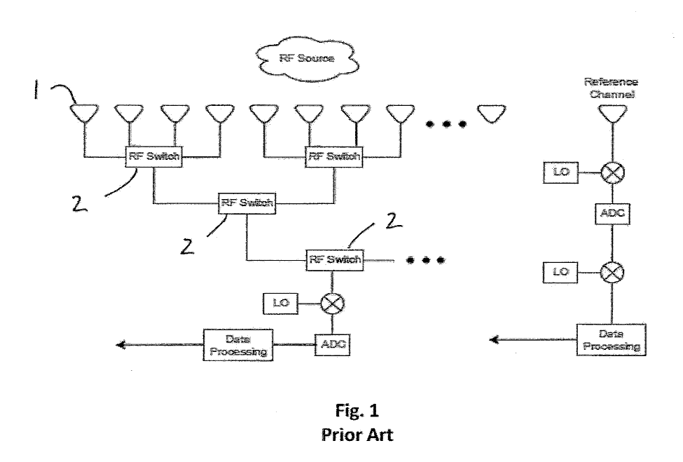

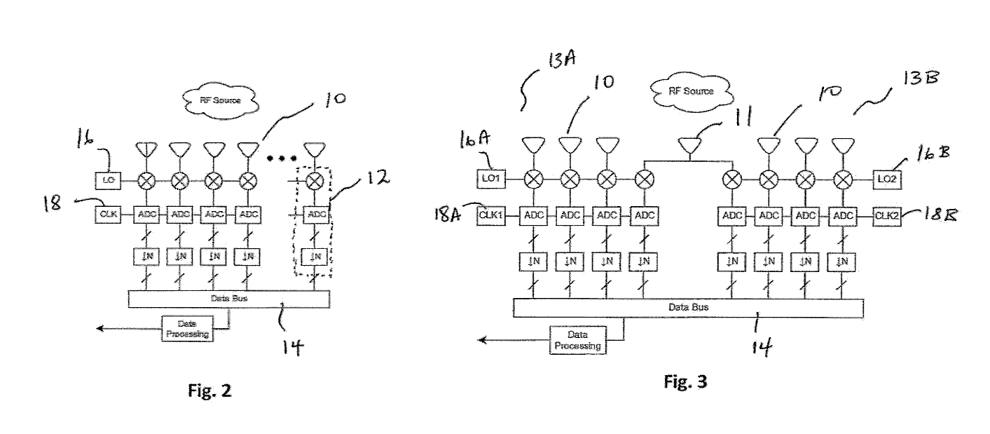

Conventional antenna measurement devices which use an array of integrated antenna probes that are electronically switched so that a large number of probes may be arrayed with a relatively fewer number of RF receivers. Exemplary devices include those described in U.S. Pat. No. 8,502,546, the entire contents of which are incorporated herein by reference, for all purposes, where permitted. As shown in prior art FIG. 1, the output from a specific probe (1) is selected by means of layered RF switches (2) which can select the output from any one of the probes. Multichannel near field measurement systems and near-field to far-field transformations are described in co-owned U.S. Pat. No. 8,502,546, the entire contents of which are incorporated herein by reference, where permitted.

The system shown in FIG. 1 sequentially selects each probe to go to a single RF receiver (downconverter and ADC) that will measure magnetic field amplitude and/or phase. The sequential selection is done by changing a large number of RF switches that are arranged in a tree structure. At high frequencies (>1 GHz), each RF switch creates loss and has substantial cost. The RF connections between the RF switches also require specialized material and contribute to overall losses and the high costs. This system also requires a separate reference channel to act as a spatial phase reference because the measurements are done sequentially.

The present invention comprises antenna measurement devices which use an array of integrated probes (10), wherein each probe (10) is associated with an unique RF receiver (12) that outputs data for downstream processing, thereby eliminating the layered switch approach shown in FIG. 1. As used herein, an “RF receiver” extracts amplitude and/or phase information from the signal outputted by a probe. However, providing a unique receiver and placing it immediately next to a probe for large arrays with thousands of probes is not possible with conventional or traditional receivers. Using cables to route signals from the probes to larger receivers at a distance from the array defeats the purpose of the having a receiver at each probe because cable losses will become significant.

As is the case with switched probes, the probe array may capture near-field data in proximity of an AUT or DUT, and the measurement device may comprise a module which transforms the data extracted by the RF receivers into far-field data. Such measurement devices measure the phase and amplitude of the magnetic field (H-field) in two orthogonal directions, in the reactive near-field, using H-field probes and project this data to the far-field using a far field transformation method such as a planar aperture distribution to angular spectrum transformation or a plane wave spectrum (PWS) transformation.

Methods and systems for calibration of the system for accurate near and far-field predictions are described in co-owned U.S. Pat. No. 9,316,714, the entire contents of which are incorporated herein by reference, where permitted.

In order to provide a unique RF receiver for each probe in a large probe array, the RF receivers (12) may be implemented in a microchip, using conventional microchip technology. A single receiver (12) may comprise a downconverter ⊗, an analog/digital converter (ADC), and an optional decimator (↓N). Receivers (12) may be grouped together to share a data bus (14), a local oscillator (16) and a clock (18), and common memory circuitry.

In one embodiment, a local oscillator (LO) bus allows each probe to be mixed down to baseband using a downconverter ⊗, with a common LO, at the probe location and a high speed analog/digital converter (ADC) will sample the baseband at a high rate (for example 53 megasamples per second (MSPS)). A clock (CLK) bus synchronizes the ADCs so that each samples at exactly the same time. Thus, each probe will be sampled independently but simultaneously. The resulting data will represent each probe, where all probes have been sampled in a simultaneous manner. As a result, a separate reference channel is not required.

If more probes are combined together than can be supported by a grouping of receivers with a common LO and CLK bus, then sharing a single probe (11) between two different receiver groups (13A and 13B) with separate LOs (16A and 16B) and clocks (18A and 18B) as is shown schematically in FIG. 3, will allow the data sequences to be aligned in post processing. For example, a single probe can be shared between two receivers on separate microchips, allowing for non-simultaneous sequences from those microchips to be aligned.

The time domain data output from each ADC can be processed to provide frequency content or to analyze signal path loss delays from the RF source. Optionally, a decimator (↓N) can be used to reduce the data set used for identifying single frequencies or a reduced set of frequencies.

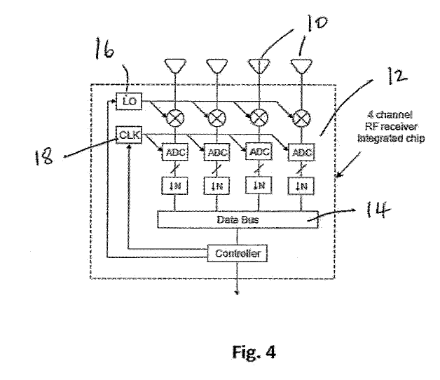

The receiver (12) comprising an ADC and a downconverter ⊗ can be embodied in a single chip or multiple sections could be combined together in a single chip to minimize the physical area needed and eliminate the need for long and high loss RF traces. Embodiments of the present invention comprise multi-channel receiver integrated chips, having a plurality of receivers. A four-channel integrated chip is shown schematically in FIG. 4, however, an integrated chip may include dozens or hundreds of channels. In one embodiment, each RF receiver is physically located close to its associated probe, separated by an RF trace distance no longer than about 1 cm. Preferably, the RF trace distance is less than about 5 mm, and more preferably, less than about 3 mm.

A system may be built with the probes embedded into a single PCB or could be built from individual antennas combined together to create an array of probes.

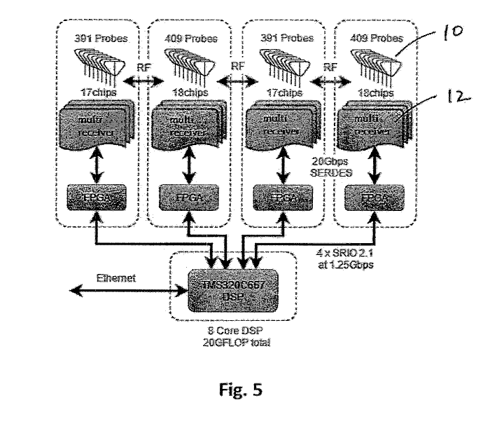

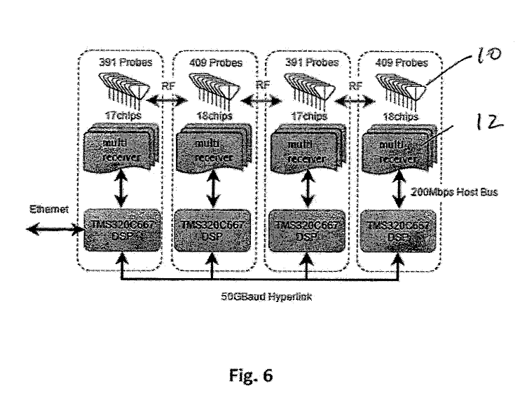

As shown schematically in FIG. 5, in one specific embodiment, a probe array of 1600 probes are each individually associated with 1600 RF receivers, which receivers are physically implemented on 70 separate microchips, each microchip having up to 24 channels. The simultaneous time sequences created by the ADCs in each receiver can be processed, for example with integrated circuits or signal processors configured by those skilled in the art to produce intelligible data for further processing. For example, FPGAs may be used to convert the data to frequency domain and to align non-simultaneous sequences from separate chips, for example by using a shared common probe as shown in FIG. 3. In one embodiment, each FPGA services 17 or 18 microchips, and approximately 400 probes, using SerDes operating at 20 Gbps in order to minimize the number of I/O pins and interconnects. The data output from the FPGA layer converges, using standard interconnects, onto a single digital signal processor (DSP) which outputs intelligible data for further processing. An alternative embodiment is illustrated in FIG. 6 where multiple DSPs are used with elimination of the FPGA layer. The downstream processing of data output from the receivers using combination of DSPs or FPGAs may be configured to balance speed and cost, as desired.

In one embodiment, a small number of the microchips, for example between 1 to 4 microchips, may be run at a time, while others are idle or shutdown in order to conserve power or minimize power usage. The non-simultaneous data may be aligned or synchronized by, for example, the shared probe configuration described above. This would impact sampling time but the overall time to capture and process data would not increase in any significant manner. If data transfer speed increase is necessary or desirable, the number of microchips in operation may be increased.

For example, with ADCs running at 53 MSPS and a desired 1 kHz equivalent Resolution Bandwidth (RBW), this requires about 32 k samples per probe, with a sample time per probe of about 0.6 ms. If one 24-channel microchip is running at a time, then the resulting sample time for an array of 1600 probes may be calculated as 1600/24×0.6 ms=40 ms. The total data for the board is 1.6 Obit (32 k samples×32 bits×1600).

Aspects of the present invention may be described with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

The description of algorithms above, and the flowchart and block diagrams in the Figures illustrate the architecture, functionality, and operation of possible implementations of systems, methods and/or computer program products according to various embodiments of the present invention. In this regard, each block in a flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The corresponding structures, materials, acts, and equivalents of all means or steps plus function elements in the claims appended to this specification are intended to include any structure, material, or act for performing the function in combination with other claimed elements as specifically claimed.

References in the specification to “one embodiment”, “an embodiment”, etc., indicate that the embodiment described may include a particular aspect, feature, structure, or characteristic, but not every embodiment necessarily includes that aspect, feature, structure, or characteristic. Moreover, such phrases may, but do not necessarily, refer to the same embodiment referred to in other portions of the specification. Further, when a particular aspect, feature, structure, or characteristic is described in connection with an embodiment, it is within the knowledge of one skilled in the art to affect or connect such module, aspect, feature, structure, or characteristic with other embodiments, whether or not explicitly described. In other words, any module, element or feature may be combined with any other element or feature in different embodiments, unless there is an obvious or inherent incompatibility, or it is specifically excluded.

It is further noted that the claims may be drafted to exclude any optional element. As such, this statement is intended to serve as antecedent basis for the use of exclusive terminology, such as “solely,” “only,” and the like, in connection with the recitation of claim elements or use of a “negative” limitation. The terms “preferably,” “preferred,” “prefer,” “optionally,” “may,” and similar terms are used to indicate that an item, condition or step being referred to is an optional (not required) feature of the invention.

The singular forms “a,” “an,” and “the” include the plural reference unless the context clearly dictates otherwise. The term “and/or” means any one of the items, any combination of the items, or all of the items with which this term is associated. The phrase “one or more” is readily understood by one of skill in the art, particularly when read in context of its usage.

What is claimed is:

1. A RF scanning system comprising a plurality of antenna probes and a plurality of RF receivers, wherein each probe is associated with a unique RF receiver which outputs data to a digital signal processor.

2. The scanning system of claim 1 wherein each RF receiver comprises a downconverter, an analog-to-digital converter, and optionally a decimator.

3. The scanning system of claim 1 or 2 wherein each RF receiver is implemented in a multi-channel microchip, comprising a controller operatively connected to a local oscillator, a clock, and a data bus, each of which is operatively connected to each RF receiver.

4. The scanning system of claim 3 comprising a plurality of microchips, wherein each microchip comprises a plurality of RF receivers.

5. The scanning system of claim 4, configured to obtain data from one microchip at a time.

6. The scanning system of one of claims 1-4, configured to sample all of the plurality of probes simultaneously

7. The scanning system of claim 5 wherein one probe is shared by receivers on separate microchips.

8. A RF scanning system comprising a plurality of antenna probes each connected to an RF receiver, wherein each antenna probe is separated from an RF receiver by an RF trace less than about 1 centimeter.

9. The scanning system of claim 8 wherein each probe is associated a unique RF receiver, and each RF receiver is implemented in a multi-channel microchip, comprising a controller operatively connected to a local oscillator, a clock, and a data bus, each of which is operatively connected to each RF receiver.

10. The scanning system of claim 9 comprising a plurality of microchips, wherein each microchip comprises a plurality of RF receivers.

11. A method of capturing data from an AUT or a DUT using a scanning system comprising a probe array comprising a plurality of probes and a plurality of RF receivers, comprising the steps of:
(a) sampling each probe with a unique RF receiver and outputting RF data from each receiver; and
(b) processing the RF data to recover measurement data from each probe.

12. The method of claim 11 wherein the RF data from each receiver is reduced to a single frequency or a reduced set of frequencies.

13. The method of claim 11 or 12, wherein the scanning system comprises a plurality of microchips, each comprising a plurality of RF receivers, wherein the data from each microchip is collected and further processed by a digital signal processor.

14. The method of claim 11, 12 or 13 wherein all RF receivers collect data simultaneously.

15. The method of claim 13 wherein an individual microchip collects data simultaneously for all its RF receivers, and the plurality of microchips collect data sequentially, and the resulting data is synchronized by the digital signal processor.
